(19) United States
(12) Patent Application Publication
(10) Pub. No.: US 2008/0265243 A1
(43) Pub. Date: Oct. 30, 2008

(54) Magnetic floating gate flash memory structures

(76) Inventors: Kie Y. Ahn, Chappaqua, NY (US); Leonard Forbes, Corvallis, OR (US)

Correspondence Address: SCHWEGMAN, LUNDBERG & WOESSNER, P.A., P.O. BOX 2938, MINNEAPOLIS, MN, 55402, US

(21) Appl. No.: 11/796,750

(22) Filed: Apr. 30, 2007

(51) Int. Cl. H01L 29/06; H01L 21/3205

(52) U.S. Cl. 257/30; 438/3; 257/E21.294; 257/E29.005

(57) ABSTRACT

Methods of forming ferromagnetic floating gate structures are described. The methods include atomic layer deposition of multiple precursor films, followed by alloying the metals in the precursor films, to form a ferromagnetic floating gate. Devices that include ferromagnetic floating gates formed with these methods are also described.

### TECHNICAL FIELD

This disclosure relates generally to non-volatile memory structures, fabrication methods, and microelectronic devices in which such non-volatile memory structures are used.

### BACKGROUND

Flash memory technology has been used because of high density, durable memory retention, and manufacturing costs among other things. Challenges exist between scaling down and charge retention in the floating gate because of small dielectric film thicknesses. Challenges also exist because of the drain turn-on effect and the possibility of capacitative coupling between adjacent memory cells.

What is needed are methods to form better flash memory cells that can address these challenges. Also needed are improved floating gate structures that can also address these challenges.

### BRIEF DESCRIPTION OF THE DRAWINGS

The abovementioned issues are addressed by the present disclosure and will be understood by reading and studying the following specification, of which the Figures are a part.

FIG. 1A shows a cross-section elevation of a semiconductor device during processing according to an embodiment of the invention;

FIG. 1B shows a cross-section elevation of the semiconductor device depicted in FIG. 1A after further processing according to an embodiment;

FIG. 1C shows a cross-section elevation of the semiconductor device depicted in FIG. 1B after further processing according to an embodiment;

FIG. 1D shows a cross-section elevation of the semiconductor device depicted in FIG. 1C after further processing according to an embodiment;

FIG. 2A shows a cross-section elevation of a semiconductor device during processing according to an embodiment of the invention;

FIG. 2B shows a cross-section elevation of the semiconductor device depicted in FIG. 1A after further processing according to an embodiment;

FIG. 3 shows a flow diagram of an example method of forming a ferromagnetic floating gate structure according to an embodiment of the invention;

FIG. 4 shows a material deposition system according to an embodiment of the invention;

FIG. 5A shows a cross-section elevation of a semiconductor device during a parallel magnetic-field programming mode method according to an embodiment of the invention;

FIG. 5B shows a cross-section elevation of the semiconductor device depicted in FIG. 5A during an anti-parallel magnetic-field retention mode method according to an embodiment;

FIG. 6 shows a block diagram of an electronic device according to an embodiment of the invention; and

FIG. 7 shows a block diagram of an electronic device according to an embodiment of the invention.

### DETAILED DESCRIPTION

In the following detailed description of the invention, reference is made to the accompanying drawings that form a part hereof and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention.

The term monolayer is defined as a material layer that is substantially one molecule thick. In some embodiments, one molecule includes one atom, while other molecules are comprised of several atoms. The term monolayer is further defined to be substantially uniform in thickness, although slight variations of between approximately 0 to 2 monolayers results in an average of a single monolayer as used in description below.

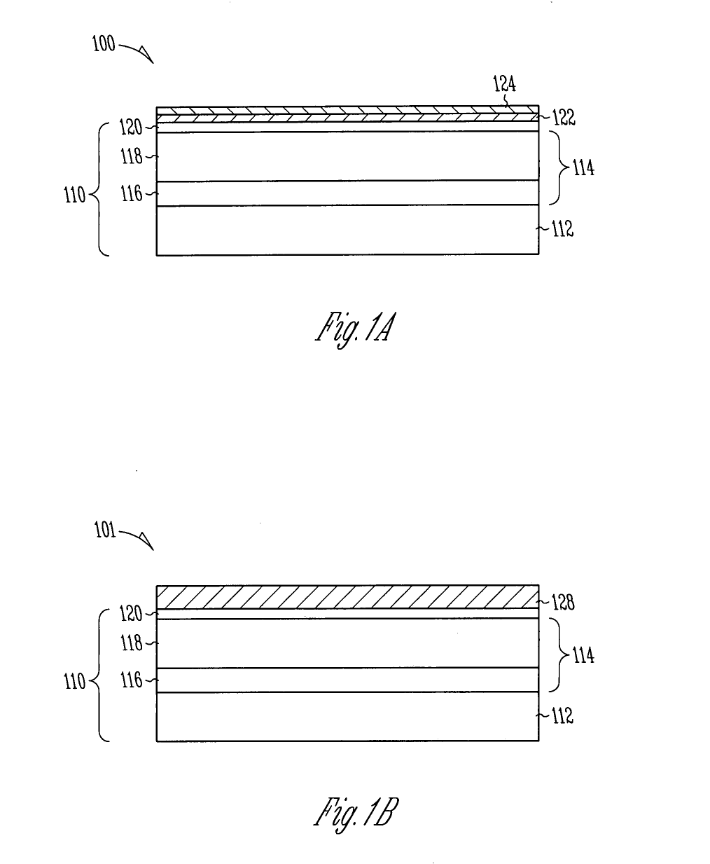

FIG. 1A shows a cross-section elevation of a semiconductor device 100 during processing according to an embodiment of the invention. A substrate 110 including a dielectric base 112 is provided, such as a low-dielectric constant (low-k) dielectric. In an embodiment, the dielectric base 112 is a polyimide material. A semiconductive section 114 includes a buried dielectric layer 116, such as a buried oxide that has been formed in monocrystalline silicon by ion implantation. The semiconductive section 114 also includes an active section 118 such as vendor-doped monocrystalline silicon, to give the semiconductive section 114 either a P-type doping or an N-type doping according to an embodiment.

A blocking dielectric film 120 is formed above the active section 118. In an embodiment, the blocking dielectric film 120 is an oxide film that is formed by thermal oxidation of exposed portions of the active section 118. In an embodiment, the blocking dielectric film 120 is also referred to as a blocking oxide 120, gate oxide 120, or as a gate dielectric 120.

In a processing embodiment, a plurality of chemically adhered monolayers is formed above the blocking dielectric film 120. FIG. 1A illustrates a first monolayer 122 that has been formed above and on the blocking dielectric film 120. In an embodiment, an atomic-layer deposition (ALD) process is carried out, such that a first monolayer 122 that contains an organometallic molecule that has been chemisorbed onto the blocking dielectric film 120. Thereafter, a subsequent monolayer 124 has been formed above the first monolayer 122.

FIG. 1B shows a cross-section elevation of the semiconductor device depicted in FIG. 1A after further processing according to an embodiment. In FIG. 1A, the plurality of monolayers includes the first monolayer 122 and the subsequent monolayer 124. The semiconductor device 101 exhibits an alloyed result of the plurality of monolayers. In an example embodiment, the ferromagnetic film 128 is formed from monolayer precursors into a binary ferromagnetic alloy.

In an example embodiment, an organo-platinum first monolayer (e.g. first monolayer 122 in FIG. 1A) was formed by ALD. A methylcyclopentadinyl trimethylplatinium (MeCpPtMe₃) composition was flowed into a microeletronic device processing tool, along with oxygen and at a temperature of about 300° C. The first monolayer 122, which contained platinum in this embodiment, was allowed to chemisorb onto the blocking dielectric film 120. The process required about 4 seconds (s), and the first monolayer 122 was observed to be about 0.45 Ångstrom (Å) in thickness.

Thereafter, the processing tool was purged of the MeCpPTMe₃ with a non-reactive gas, and an organo-iron subsequent monolayer (e.g. second monolayer 124 in FIG. 1A) was formed above and on the first monolayer 122. A homoleptic N,N″-dialkylactamidinato iron compound was used in the presence of molecular hydrogen gas.

The plurality of two monolayers 122 and 124, were reacted under alloying conditions to form the ferromagnetic film 128. The amount of chemisorbed platinum first monolayer 122 limited the alloying effect. Thereafter, the processing tool was purged of excess vapors of the organo-iron feed.

In an embodiment, an FePt ferromagnetic film 128 is formed. In an embodiment, a CuPt ferromagnetic film 128 is formed. In an embodiment wherein only two precursor layers are formed, the thickness of the FePt magnetic film 128 is about 3 Å. In an embodiment, the thickness of the magnetic film 128 is in a range from about 3 Å to about 300 Å. In an embodiment the thickness of the magnetic film 128 is in a range from about 10 Å to about 50 Å.

FIG. 1C shows a cross-section elevation of the semiconductor device depicted in FIG. 1B after further processing according to an embodiment. The semiconductor device 102 has been further processed by placing a tunneling dielectric film 130 above and on the ferromagnetic film 128. In an embodiment, the tunneling dielectric film 130 is an oxide such as a silicon oxide. Thereafter, a control gate film 132 is formed above and on the tunneling dielectric film 130. The control gate film 132 can be made from a metal or metal alloy according to an embodiment. In an embodiment, the control gate film 132 is an ALD-formed film, made by the chemisorption of a metal or metal alloy precursor onto the tunneling dielectric film 130.

A mask 134 is patterned above and on the control gate film 132 in preparation of forming a gate stack.

FIG. 1D shows a cross-section elevation of the semiconductor device depicted in FIG. 1C after further processing according to an embodiment. The semiconductor device 103 has been further processed by etching around the mask 134 (FIG. 1C) to pattern the structures into a blocking dielectric 121, a floating gate 129, a tunneling dielectric 131, and a control gate 133. FIG. 1D also indicates further processing to form self-aligned source/drain (S/D) regions in the active section 118. Further processing, such as forming spacer dielectrics on the gate stack and bit-line connections to the active section 118, can be carried out according to conventional technique.

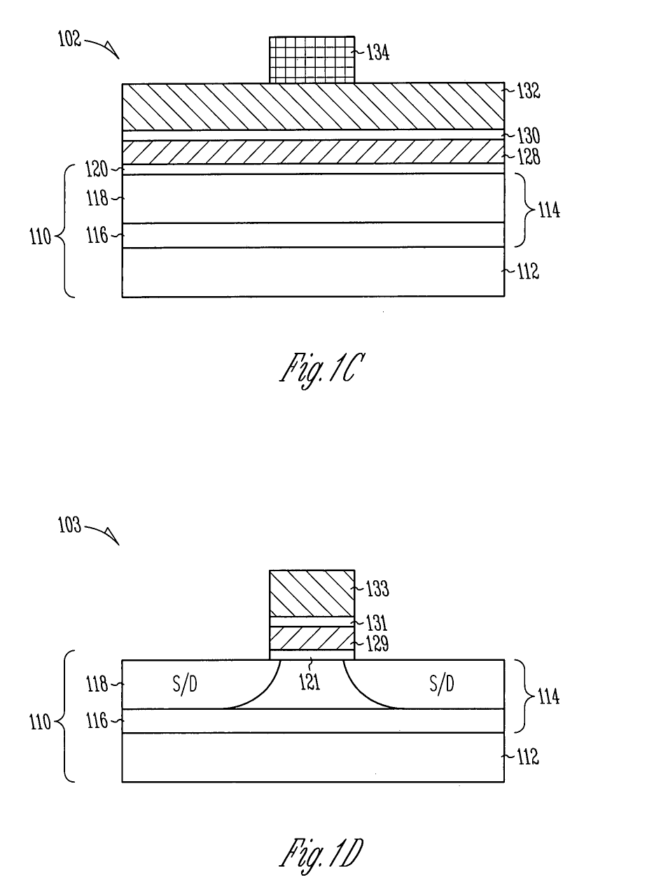

FIG. 2A shows a cross-section elevation of a semiconductor device 200 during processing according to an embodiment of the invention. The semiconductor device 200 is similar to the semiconductor device 100 depicted in FIG. 1A. The semiconductor device 200 includes a substrate 210 including a dielectric base 212, a semiconductive section 214 including a buried dielectric layer 216 and an active section 218. The semiconductor device 200 also includes a blocking dielectric film 220 above the active section 218.

FIG. 2A represents an embodiment wherein a first monolayer 222 has been formed upon the substrate 210, a second monolayer 226 has been formed above and on the first monolayer 222, and a subsequent monolayer 224 has been formed above and on the second monolayer 226. This embodiment includes processes where more than two precursor monolayers are used to form a single ferromagnetic film.

FIG. 2B shows a cross-section elevation of the semiconductor device depicted in FIG. 2A after further processing according to an embodiment. The semiconductor device 201 has been processed such that the plurality of monolayers, 222, 226, and 224 (FIG. 2A) have been alloyed into a ferromagnetic film 228.

It can now be appreciated that ferromagnetic films can be fabricated from one to more than two precursor monolayers.

In an embodiment, an FePt film 129 (FIG. 1D) is made by the dual-monolayer deposition process described above. In an embodiment, a CuFe film 129 is made by the dual-monolayer deposition process. In an embodiment, a NiFe film 129 is made by the dual-monolayer deposition process. In an embodiment, a CoFe film 129 is made by the dual-monolayer deposition process.

In an embodiment an FeNiPt film 228 (FIG. 2B) is made from monolayer precursors of the first monolayer 224, the second monolayer 226, and the subsequent monolayer 224, as depicted in FIG. 2A. In an embodiment an FeNiCu film 228 is made from monolayer precursors of the first monolayer 224, the second monolayer 226, and the subsequent monolayer 224. In an embodiment an FeNiCo film 228 is made. In an embodiment an FeCuPt film 228 is made. In an embodiment an FeCuCo film 228 is made. In an embodiment an FeCoNi film 228 is made. Other ferromagnetic films can be made by varying starting materials that are known to be ferromagnetic film precursors. For example, Heusler alloys, which are nonferrous ferromagnetic alloys, can be used, such as two parts copper, one part manganese, and one part tin. In this embodiment, the first and second monolayers 224 and 226 are manganese and tin, and the subsequent monolayer is copper, in these ratios.

The methods described form a unique structure compared to other deposition methods. Using monolayer deposition methods, a ferromagnetic floating gate structure can be formed with step coverage over surface topography that is superior to other deposition techniques. Other processing variations provide a fine crystal distribution such as a nanocrystalline ferromagnetic floating gate structure. Micro-scale and nano-scale crystal structures provide unique physical properties such as highly durable films.

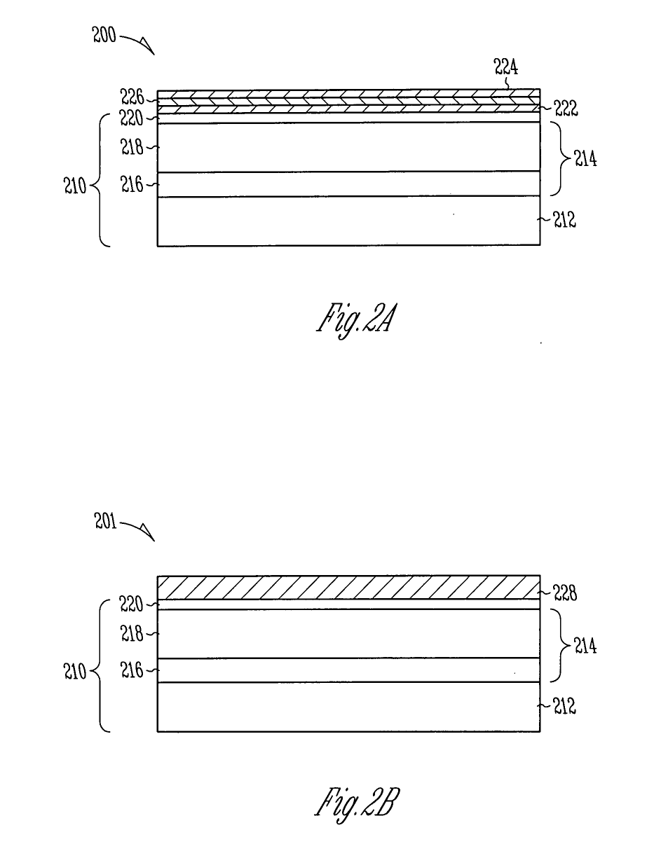

FIG. 3 shows a flow diagram 300 of an example method of forming a ferromagnetic floating gate structure according to an embodiment of the invention. In process 310, a monolayer that includes a first ferromagnetic floating gate structure precursor is deposited. In an embodiment, the first monolayer is iron that is chemisorbed.

At 312, a purge of the processing tool is carried out that leaves the first monolayer chemisorbed.

At 320, the process includes forming a subsequent monolayer above the first monolayer. In an embodiment, a platinum subsequent monolayer is formed above and on the iron first monolayer.

In the embodiment, wherein a plurality of more than two monolayers is formed, a purge of the processing tool is carried out at 328, followed by forming a second monolayer above and on the first monolayer. Thereafter, a purge is carried out at 312, and the subsequent monolayer is formed above the first monolayer. In a three monolayer processing embodiment, the second monolayer is formed above and on the first monolayer, and the subsequent monolayer is formed above and on the second monolayer. It can now be appreciated that this process may include a third monolayer and the fourth monolayer is the subsequent monolayer.

At 340 the plurality of monolayers is processed to form a magnetic floating gate structure. In the processing embodiment, mixing includes processes such as annealing or diffusion mixing of the various monolayer precursors. In the processing embodiments, the organic materials that carry the selected metals are driven off by either decomposition or volatilization.

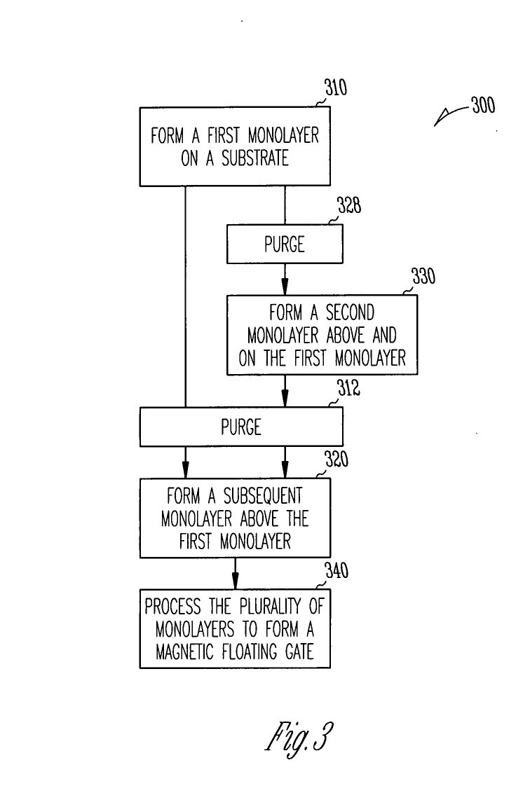

FIG. 4 shows an embodiment of an atomic layer deposition system 400 for processing a plurality of monolayers into a ferromagnetic floating gate structure according to the teachings of the present invention. The elements depicted are those elements necessary for discussion of the present invention such that those skilled in the art may practice the present invention without undue experimentation. Processing variable such as temperature and pressure, duration, etc. are chosen to reach a desired structure morphology.

In ALD, gaseous precursors are introduced one at a time to the substrate surface mounted within a reaction chamber (or tool). This introduction of the gaseous precursors takes the form of pulses of each gaseous precursor. Between the pulses, the reaction chamber is purged with a gas, which in many cases is an inert gas, or the reaction chamber is evacuated.

In a chemisorption-saturated ALD (CS-ALD) process, during the first pulsing phase, reaction with the substrate occurs with the precursor saturatively chemisorbed at the substrate surface. Subsequent pulsing with a purging gas removes precursor excess from the reaction chamber.

The second pulsing phase introduces another precursor on the substrate where the growth reaction of the desired film takes place. Subsequent to the film growth reaction, reaction byproducts and precursor excess are purged from the reaction chamber. With favorable precursor chemistry where the precursors adsorb and react with each other on the substrate aggressively, one ALD cycle can be performed in less than one second in properly designed flow type reaction chambers. Typically, precursor pulse times range from about 0.5 second to about 2 to 3 seconds.

In ALD, the saturation of all the reaction and purging phases makes the growth self-limiting. This self-limiting growth results in large area uniformity and conformality, which has important applications for applications such as planar substrates, deep trenches, and in material deposition on porous materials, other high surface area materials, powders, etc. Examples include, but are not limited to organometallic ferromagnetic film precursors. Significantly, ALD provides for controlling deposition thickness in a straightforward, simple manner by controlling the number of growth cycles. Consequently, a laminate can be formed such that, although the first monolayer may be the thickness of one or two elements of metal, a laminate can be formed to achieve thicker ferromagnetic floating gate structures. In an embodiment, a two-metal, e.g. FePt, ferromagnetic floating gate structure is formed, but the ferromagnetic floating gate structure is made from at least three monolayers, and in an embodiment, is made from four monolayers.

The precursors used in an ALD process may be gaseous, liquid or solid. Typically, liquid or solid precursors are volatile. The vapor pressure must be high enough for effective mass transportation. Also, solid and some liquid precursors are heated inside the reaction chamber and introduced through heated tubes to the substrates. The necessary vapor pressure is reached at a temperature below the substrate temperature to avoid the condensation of the precursors on the substrate. Due to the self-limiting growth mechanisms of ALD, relatively low vapor pressure solid precursors can be used though evaporation rates may somewhat vary during the process because of changes in their surface area.

There are several other considerations for precursors used in ALD. Thermal stability of precursors at the substrate temperature is a factor because precursor decomposition affects the surface control. ALD is heavily dependent on the reaction of the precursor at the substrate surface. A slight decomposition, if slow compared to the ALD growth, can be tolerated.

The precursors chemisorb on or react with the surface, though the interaction between the precursor and the surface, as well as the mechanism for the adsorption, is different for different precursors. The molecules at the substrate surface react aggressively with the second precursor to form the desired solid film. Additionally, precursors should not react with the film to cause etching, and precursors should not dissolve in the film. Using highly reactive precursors in ALD contrasts with the selection of precursors for conventional CVD.

The by-products in the reaction are typically gaseous in order to allow their easy removal from the reaction chamber. Further, the by-products should not react or adsorb on the surface.

In a reaction sequence ALD (RS-ALD) process, the self-limiting process sequence involves sequential surface chemical reactions. RS-ALD relies on chemistry between a reactive surface and a reactive molecular precursor. In an RS-ALD process, molecular precursors are pulsed into the ALD reaction chamber separately. The metal precursor reaction at the substrate is typically followed by an inert gas pulse or chamber evacuation to remove excess precursor and by-products from the reaction chamber prior to pulsing the next precursor of the fabrication sequence.

Using RS-ALD, films can be layered in equal metered sequences that are essentially identical in chemical kinetics, deposition per cycle, composition, and thickness. RS-ALD sequences generally deposit less than a full layer per cycle. Typically, a deposition or growth rate of about 0.25 to about 2.00 Å per RS-ALD cycle can be realized.

In these embodiments, RS-ALD processes provide for use of low temperature and mildly oxidizing processes, for growth thickness dependent solely on the number of cycles performed, and ability to engineer multilayer laminate films with resolution of one to two monolayers.

RS-ALD processes provide for robust deposition of films or other structures. Due to the unique self-limiting surface reaction of materials that are deposited using RS-ALD, such films are free from processing challenges such as first wafer effects and chamber dependence. Accordingly, RS-ALD processes are easy to transfer from development to production and from 200 to 300 mm wafer sizes in production lines. Thickness depends solely on the number of cycles. Thickness can therefore be dialed in by controlling the number of cycles.

Laminate structures of multiple layers formed using ALD can also be subsequently processed to mix the individual layers together. For example, a laminate structure can be annealed to mix a plurality of different layers together, thus forming an alloy or a mixture of layer chemistries. By forming a laminate structure using ALD, and subsequently mixing the layers, the chemistry of the resulting structure is precisely controlled. Because the laminate is made up of self-limiting monolayers over a known surface area, the number of molecules from each individual layer are known to a high degree of accuracy. Chemistry can be controlled by adding or subtracting one or more layers in the laminate.

In an embodiment, multiple alternating monolayers are laminated above the blocking dielectric, before processing.

Referring to FIG. 4, a substrate 410 is located inside a reaction chamber 420 of the ALD system 400. Also located within the reaction chamber 420 is a heating element 430 which is thermally coupled to substrate 410 to control the substrate temperature. A gas-distribution fixture 440 introduces precursor gases to the substrate 410. Each precursor gas originates from individual gas sources 451-454 whose flow is controlled by mass-flow controllers 456-459, respectively. The gas sources 451-454 provide a precursor gas either by storing the precursor as a gas or by providing a location and apparatus for evaporating a solid or liquid material to form the selected precursor gas.

Also included in the ALD system 400 are purging gas sources 461, 462, each of which is coupled to mass-flow controllers 466, 467, respectively. The gas sources 451-454 and the purging gas sources 461, 462 are coupled by their associated mass-flow controllers to a common gas line or conduit 470 which is coupled to the gas-distribution fixture 440 inside the reaction chamber 420. The gas conduit 470 is also coupled to vacuum pump, or exhaust pump, 481 by a mass-flow controller 486 to remove excess precursor gases, purging gases, and by-product gases at the end of a purging sequence from the gas conduit 470.

A vacuum pump, or exhaust pump, 482 is coupled by mass-flow controller 487 to remove excess precursor gases, purging gases, and by-product gases at the end of a purging sequence from the reaction chamber 420. For convenience, control displays, mounting apparatus, temperature sensing devices, substrate maneuvering apparatus, and necessary electrical connections as are known to those skilled in the art are not shown in FIG. 4. Although ALD system 400 is illustrated as an example, other ALD systems may be used.

Although a number of examples of precursors, oxidizers, and process conditions are listed above, the invention is not so limited. One of ordinary skill in the art, having the benefit of the present disclosure will recognize that other chemistries and process conditions that form ferromagnetic monolayer precursors can be used.

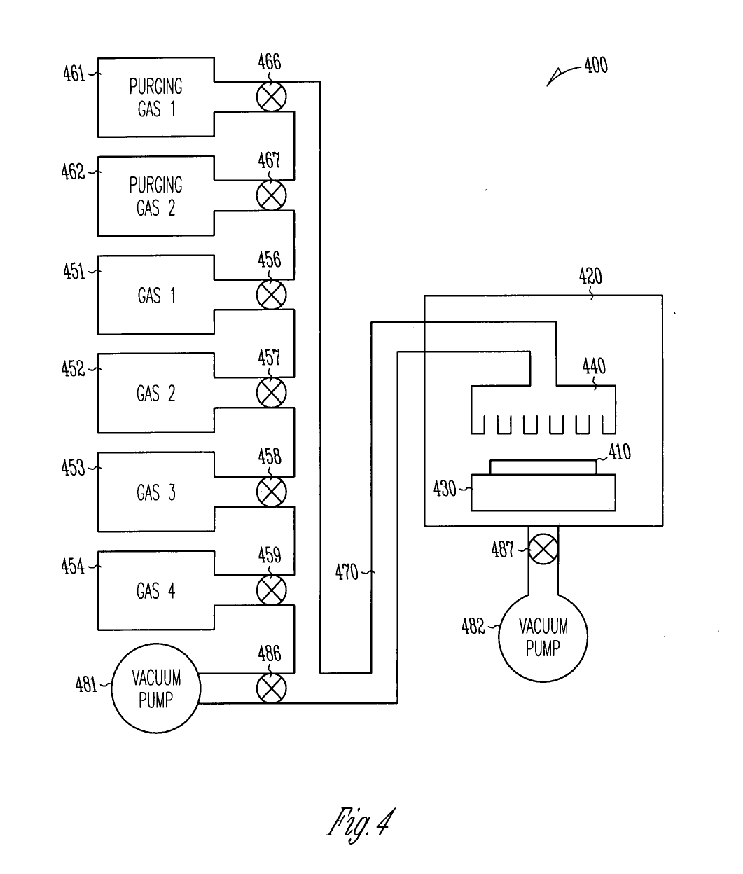

FIG. 5A shows a cross-section elevation of a semiconductor device 500 during a parallel magnetic-field programming mode method according to an embodiment of the invention. The semiconductor device 500 has includes a substrate 510 with a patterned gate stack. The patterned gate stack includes a blocking dielectric 521, a floating gate 529, a tunneling dielectric 531, and a control gate 533. Other structures are similar to those depicted in FIG. 1D. The floating gate 529 is depicted in parallel programming mode.

FIG. 5B shows a cross-section elevation of the semiconductor device depicted in FIG. 5A during an anti-parallel magnetic-field retention mode method according to an embodiment. The floating gate 529 is depicted in antiparallel retention mode.

A method of operation of the magnetic flash memory includes a one-transistor type memory cell. The floating gate 529 can also be referred to as a pinned layer. The tunneling dielectric 531 (also referred to as a tunneling oxide), the floating gate 529 (also referred to as the pinned layer), and the control gate 533 (also referred to as the free layer) are referred to as a magnetic tunneling diode (MTD). The control gate 533, which can be a NiFe material acts as a free layer and the floating gate 529, which can be an FePt material acts as the pinned layer in the MTD.

Tunneling between the free layer 533 and the pinned layer 529 depends upon the relative magnetic polarization of these two materials and their structures, whether parallel or antiparallel. Tunneling probability is high for the parallel polarization of both the free layer 533 and the pinned layer 529, and it is lower in the case of the antiparallel polarization of these layers. Parallel polarization is preserved in programming mode and reading mode, whereas antiparallel polarization is preserved in the retention mode for an electronically erasable-programmable read-only memory EEPROM device such as flash memory. Magnetic fields are switched to change polarization between parallel and antiparallel, by using currents that flow through the bit line (BL) and the word line (WL) as these terms are understood in the art.

A positive high voltage or 0V is applied to the control gate 533, depending upon whether the programming data is a “1” or a “0”, respective, in the programming mode or the erasing mode. In the programming mode, the control gate is maintained at the ground potential and a positive voltage is applied to the source and drain to inject the electrons from the control gate into the floating gate when data “1” is written.

In the erasing mode, a positive voltage is applied to the control gate through the word line, and the source and drain are maintained at the ground potential to emit electrons from the floating gate to the control gate. Excellent retention characteristics are expected even if a thin tunneling oxide is used, because the antiparallel polarization condition decreases the tunneling probability of the MTD.

In a magnetic flash memory structure that is made according to any of the process embodiments set forth in this disclosure, a high programming and erasing speed can be expected.

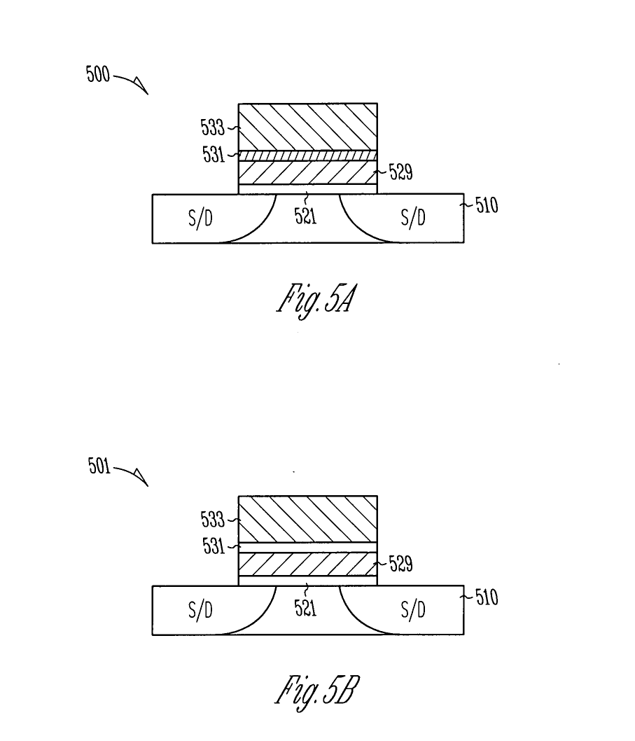

FIG. 6 illustrates an electronic device 600 that includes ferromagnetic floating gate structures formed using monolayer deposition methods such as ALD as described above. The electronic device 600 includes a first component 620 that benefits from ferromagnetic floating gate structures. Examples of first component 620 include flash memory arrays. In an embodiment, the first component 620 is a processor that includes flash memory arrays that are used for booting up the processor. In these examples, device operation is improved with the thickness of the ferromagnetic floating gate structures.

In an embodiment, the device 600 further includes a power source 630. The power source 630 is electrically connected to the first device component 620 using interconnecting circuitry 640. In an embodiment, the interconnecting circuitry 640 includes ferromagnetic floating gate structures formed from monolayers using ALD methods described above. In addition to depositing material as described above, techniques such as lithography with masks, and/or etching, etc., can be used to pattern conducting circuitry.

In an embodiment, the device 600 further includes a second device component 610. The second component is electrically connected to the first component 620 using interconnecting circuitry 642. Likewise, in one embodiment, the interconnecting circuitry 642 includes ferromagnetic floating gate structures that are formed using methods described above. Examples of second device components 610 include signal amplifiers, flash memory, logic circuitry or other microprocessing circuits, etc. Aside from interconnecting circuitry, in an embodiment, the first device component 620 and/or the second device component 610 includes ferromagnetic floating gate structures formed starting from monolayer precursors and by using methods described above.

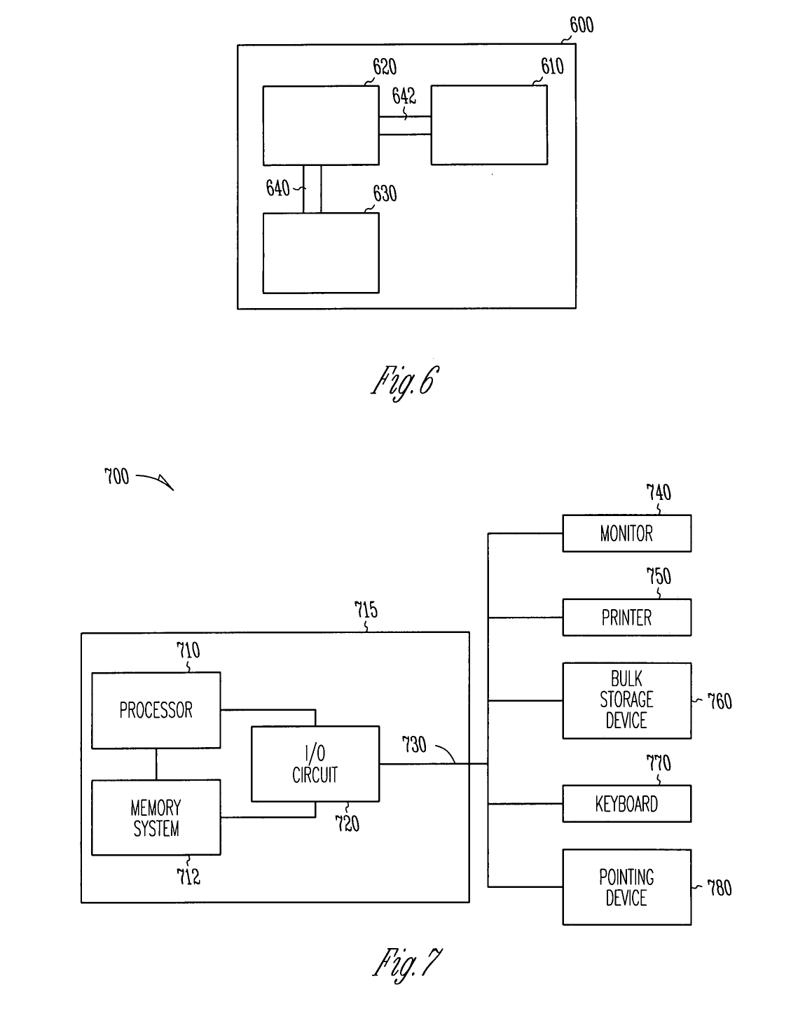

FIG. 7 shows one specific example of a computer system including ferromagnetic floating gate structures formed as described above. The computer system 700 contains a processor 710 and a memory system 712, housed in a computer unit 715. The computer system 700 is but one example of an electronic system containing another electronic system. In an embodiment, the computer system 700 contains an input-output (I/O) circuit 720 that is coupled to the processor 710 and the memory system 712. In an embodiment, the computer system 700 contains user interface components that are coupled to the I/O circuit 720. In an embodiment, a ferromagnetic floating gate structure is coupled to one of a plurality of I/O pads or pins 730 of the I/O circuit 720. The I/O circuit 720 can then be coupled to at least one of a monitor 740, a printer 750, a bulk storage device 760, a keyboard 770 and a pointing device 780. It will be appreciated that other components are often associated with the computer system 700 such as modems, device driver cards, additional storage devices, etc. It will further be appreciated that the processor 710, the memory system 712, the I/O circuit 720, and partially isolated structures or data storage devices of computer system 700 can be incorporated on a single integrated circuit. Such single package processing units may reduce the communication time between the processor 710 and the computer system 700.

This Detailed Description refers to the accompanying drawings that show, by way of illustration, specific aspects and embodiments in which the present disclosure may be practiced. These embodiments are described in sufficient detail to enable those skilled in the art to practice the disclosed embodiments. Other embodiments may be utilized and structural, logical, and electrical changes may be made without departing from the scope of the present disclosure. The various embodiments are not necessarily mutually exclusive, as some embodiments can be combined with one or more other embodiments to form new embodiments.

The terms “wafer” and “substrate” used in the following description include any structure having an exposed surface with which to form an electronic device or device component such as a component of an integrated circuit (IC). The term substrate is understood to include semiconductor wafers. The term substrate is also used to refer to semiconductor structures during processing and may include other layers, such as silicon-on-insulator (SOI), etc. that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to include semiconductors and the term insulator or dielectric is defined to include any material that is less electrically conductive than the materials referred to as conductors.

The term “horizontal” as used in this document is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side” (as in “sidewall”), “higher”, “lower”, “over” and “under” are defined with respect to the conventional plane or surface being on the top surface of the wafer or substrate, regardless of the orientation of the wafer or substrate.

The Detailed Description is, therefore, not to be taken in a limiting sense, and the scope of this disclosure is defined only by the appended claims, along with the full scope of equivalents to which such claims are entitled.

The Abstract is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, various features may be grouped together to streamline the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus the following claims are hereby incorporated into the Detailed Description, with each claim standing on its own as a separate embodiment.

1. A process of forming a magnetic tunneling diode, comprising:
forming a plurality of chemically adhered monolayers on a substrate; and
processing the plurality of chemically adhered monolayers to form a floating-gate ferromagnetic structure therefrom.

2. The process of claim 1, wherein processing includes alloying the plurality of chemically adhered monolayers on the substrate.

3. The process of claim 1, wherein the substrate includes a blocking dielectric layer, further including:
forming a tunneling dielectric above and on the floating-gate ferromagnetic structure; and
forming a control-gate above the floating-gate ferromagnetic structure.

4. The process of claim 1, wherein the substrate is a blocking dielectric layer, further including:
forming a tunneling dielectric above and on the floating-gate ferromagnetic structure; and
forming a control-gate above the floating-gate ferromagnetic structure, wherein the floating-gate ferromagnetic structure is an FePt alloy, and the control-gate is a NiFe alloy.

5. The process of claim 1, wherein forming the plurality of chemically adhered monolayers includes disposing an organo-iron monolayer against an organo-platinum monolayer.

6. The process of claim 1, wherein forming the plurality of chemically adhered monolayers includes disposing an organo-iron monolayer against an organo-copper monolayer.

7. The process of claim 1, wherein forming the plurality of chemically adhered monolayers includes disposing an organo-iron monolayer against an organo-cobalt monolayer.

8. The process of claim 1, wherein forming the plurality of chemically adhered monolayers includes disposing an organo-iron monolayer against an organo-nickel monolayer.

9. The process of claim 1, wherein the plurality of chemically adhered monolayers are processed to form a nonferrous ferromagnetic alloy.

10. A process of forming a magnetic tunneling diode, comprising:
forming an organo-platinum first monolayer on a blocking dielectric layer of a semiconductive substrate that is disposed in a tool;
purging the tool;
forming an organo-iron second monolayer above and on the organo-platinum first monolayer to form a plurality of chemically adhered monolayers; and
processing the plurality of chemically adhered monolayers to form a ferromagnetic film therefrom.

11. The process of claim 10, further including patterning a tunneling dielectric film and control gate film, disposed above the ferromagnetic film, to form a ferromagnetic floating gate structure from the ferromagnetic film.

12. The process of claim 10, further including forming a control gate film above the ferromagnetic film, wherein the control gate film is made of a NiFe material.

13. The process of claim 10, wherein processing the plurality of chemically adhered monolayers to form a ferromagnetic film includes forming multiple alternating layers of organo-iron and organo-platinum monolayers.

14. The process of claim 10, further including:
forming a control gate film above the ferromagnetic film, wherein the control gate film is made of a NiFe material; and
patterning a tunneling dielectric film and the control gate film, disposed above the ferromagnetic film, to form a ferromagnetic floating gate structure from the ferromagnetic film.

15-20. (canceled)

21. A process of forming a magnetic tunneling diode, comprising:
forming a blocking dielectric on a substrate;
forming a first plurality of chemically adhered monolayers on the blocking dielectric;
processing the first plurality of chemically adhered monolayers to form a ferromagnetic floating-gate, the ferromagnetic floating-gate including platinum;
forming a tunneling dielectric on the ferromagnetic floating-gate;
forming a second plurality of chemically adhered monolayers on the tunneling dielectric; and
processing the second plurality of chemically adhered monolayers to form a ferromagnetic control gate, the ferromagnetic control gate including iron.

22. The process of claim 21, wherein forming the first plurality of chemically adhered monolayers comprises using a methylcyclopentadinyl trimethylplatinium composition.

23. The process of claim 21, wherein forming the second plurality of chemically adhered monolayers comprises using a homoleptic N,N″-dialkylactamidinato iron compound.

24. The process of claim 21, wherein processing the first plurality of chemically adhered monolayers to form the ferromagnetic floating-gate includes forming the ferromagnetic floating-gate containing copper.

25. The process of claim 21, wherein processing the first plurality of chemically adhered monolayers to form the ferromagnetic floating-gate includes forming the ferromagnetic floating-gate as a three metal alloy.

26. The process of claim 21, wherein the method comprises:
forming an active section on a buried dielectric layer in the substrate; and
processing the blocking dielectric to dispose the blocking dielectric on the active section.
